(19) United States
(12) Patent Application Publication
(10) Pub. No.: US 2012/0069260 A1
(43) Pub. Date: Mar. 22, 2012

(54) ACTIVE MATRIX SUBSTRATE, LIQUID CRYSTAL DISPLAY DEVICE INCLUDING THE SAME, AND METHOD FOR FABRICATING ACTIVE MATRIX SUBSTRATE

(75) Inventor: Katsunori Misaki, Yonago-shi (JP)

(73) Assignee: SHARP KABUSHIKI KAISHA, Osaka-shi, Osaka (JP)

(21) Appl. No.: 13/319,362

(22) PCT Filed: Feb. 22, 2010
(86) PCT No.: PCT/JP10/01150

§ 371 Date: Nov. 8, 2011

(30) Foreign Application Priority Data
Jun. 22, 2009 (JP) 2009-147794

(51) Int. Cl. G02F 1/1368; H01L 33/62

(52) U.S. Cl. 349/43; 257/59; 438/34; 257/E29.273; 257/E33.062

(57) ABSTRACT

A recess, which extends through an interlayer insulating film and a part of a gate insulating film portion forming a dielectric layer of a storage capacitor and is covered by a pixel electrode, is formed in the interlayer insulating film and a gate insulating film. A pixel electrode portion corresponding to a bottom of the recess forms an upper electrode of the storage capacitor.

### TECHNICAL FIELD

The present invention relates to active matrix substrates, liquid crystal display (LCD) devices including the same, and methods for fabricating an active matrix substrate.

### BACKGROUND ART

Active matrix drive type LCD devices have a thin film transistor (hereinafter referred to as the “TFT”) at every pixel as a minimum unit of an image, and are configured to provide a desired display by applying a signal voltage to each pixel selected via the TFT. The LCD devices further have a storage capacitor at each pixel, which holds a signal voltage while the TFT is off.

The storage capacitor has upper and lower electrodes that face each other with a dielectric layer interposed therebetween, and is formed, together with the TFT, etc., on an active matrix substrate in order to simplify the fabrication process and to reduce fabrication cost. For example, in the case of a bottom-gate TFT, the lower electrode is formed simultaneously with a gate electrode, the dielectric layer is formed simultaneously with a gate insulating film, and the upper electrode is formed simultaneously with a source electrode and a drain electrode.

As described above, in the case of forming the storage capacitor together with the TFT, the upper electrode and the lower electrode are respectively made of the same non-transmissive metal materials as those of electrodes forming the TFT. Thus, a region provided with the storage capacitor is non-transmissive, and thus causes a decrease in the aperture ratio of a pixel. Since the gate insulating film is used as a dielectric layer of the storage capacitor, the dielectric layer is designed so as to have a thickness large enough to allow the gate insulating film to have sufficient dielectric strength in the TFT. Thus, in order to form a storage capacitor having predetermined capacitance, each of the upper electrode and the lower electrode needs to have a predetermined area or more according to the thickness of the gate insulating film. Accordingly, as the pixel size decreases with an increase in definition of pixels, the storage capacitor occupies a larger area in each pixel, thereby decreasing the aperture ratio of the pixel. Thus, configurations of storage capacitors having predetermined capacitance even if the upper and lower electrodes have smaller areas have been proposed as a solution to this problem.

For example, Patent Document 1 discloses a configuration in which a gate insulating film on a lower electrode of a storage capacitor is removed by etching, and a dielectric layer of the storage capacitor is provided on the lower electrode separately from the gate insulating film. According to Patent Document 1, the area of the storage capacitor can be reduced relative to the area of the pixel electrode by reducing the thickness of the dielectric layer of the storage capacitor or increasing the dielectric constant of the dielectric layer to increase the capacitance of the storage capacitor per unit area.

### CITATION LIST

### Patent Document

PATENT DOCUMENT 1: Japanese Patent Publication No. 2001-13520

### SUMMARY OF THE INVENTION

### Technical Problem

However, in the case where the gate insulating film on the lower electrode is removed by etching, and the dielectric layer of the storage capacitor is provided on the lower electrode separately from the gate insulating film as described in Patent Document 1, an additional photomask is required to form a resist layer, as a mask for etching, on the gate insulating film, and processes such as resist coating, exposure, development, etc. are required to form the resist layer. This significantly increases the number of fabrication steps, and therefore this configuration has room for improvement.

The present invention was developed in view of the above problems, and it is an object of the present invention to form a storage capacitor having desired capacitance, without causing an increase in the number of fabrication steps and a decrease in the aperture ratio of a pixel.

### Solution to the Problem

In order to achieve the above object, the present invention is configured to make a gate insulating film portion corresponding to a lower electrode thinner when forming a contact hole in an interlayer insulating film and a gate insulating film, and to form an upper electrode by a part of a pixel electrode.

Specifically, an active matrix substrate according to the present invention includes: a base substrate; a TFT having a gate electrode provided on the base substrate, a gate insulating film provided so as to cover the gate electrode, and a drain electrode provided on the gate insulating film; a storage capacitor having a lower electrode provided on the base substrate and covered by the gate insulating film, a dielectric layer formed by a gate insulating film portion corresponding to the lower electrode, and an upper electrode provided so as to overlap the lower electrode with the dielectric layer interposed therebetween; an interlayer insulating film provided so as to cover the TFT, and having a first contact hole that reaches the drain electrode; and a pixel electrode provided on the interlayer insulating film, and electrically connected to the drain electrode via the first contact hole. A recess, which extends through the interlayer insulating film and a part of the gate insulating film and is covered by the pixel electrode, is formed in the interlayer insulating film and the gate insulating film so as to make the dielectric layer thinner than a gate insulating film portion corresponding to the gate electrode, and the upper electrode is formed by a pixel electrode portion corresponding to a bottom of the recess.

In the active matrix substrate having the above configuration, it is preferable that a terminal portion, which is covered by the gate insulating film and is electrically connected to the lower electrode, be provided on the base substrate, that a second contact hole be formed in the interlayer insulating film and the gate insulating film so as to reach the terminal portion, that a connection electrode, which is electrically connected to the terminal portion via the second contact hole and is configured to apply a common voltage to the terminal portion, be provided separately from the pixel electrode on the interlayer insulating film, that the TFT further have a semiconductor layer, which overlaps the gate electrode with the gate insulating film interposed therebetween and is electrically connected to the drain electrode, and that the recess extend through an etching suppressing layer on the gate insulating film corresponding to the lower electrode, the etching suppressing layer being made of a same film as the semiconductor layer.

An LCD device according to the present invention includes: the active matrix substrate having the above configuration; a counter substrate placed so as to face the active matrix substrate; and a liquid crystal layer provided between the active matrix substrate and the counter substrate.

A method for fabricating an active matrix substrate according to the present invention is a method for fabricating an active matrix substrate including a TFT having a gate electrode provided on a base substrate, a gate insulating film provided so as to cover the gate electrode, and a drain electrode provided on the gate insulating film, and a storage capacitor having a lower electrode provided on the base substrate and covered by the gate insulating film, a dielectric layer formed by a gate insulating film portion corresponding to the lower electrode, and an upper electrode provided so as to overlap the lower electrode with the dielectric layer interposed therebetween, the method including: a first electrode formation step of forming a conductive film on the base substrate, and then patterning the conductive film to simultaneously form the gate electrode and the lower electrode; a gate insulating film formation step of forming the gate insulating film so as to cover the gate electrode and the lower electrode; a second electrode formation step of forming the drain electrode on the gate insulating film; an interlayer insulating film formation step of forming an interlayer insulating film so as to cover the drain electrode and to overlap the lower electrode with the gate insulating film interposed therebetween; an insulating film patterning step of patterning the interlayer insulating film and the gate insulating film at a time to form in the interlayer insulating film a contact hole that reaches the drain electrode, and to form a recess, which extends through the interlayer insulating film and a part of the gate insulating film, so as to make the dielectric layer thinner than a gate insulating film portion corresponding to the gate electrode; and a pixel electrode formation step of forming a pixel electrode on the interlayer insulating film having the contact hole formed therein, so that the pixel electrode electrically connects to the drain electrode via the contact hole and covers the recess, wherein a pixel electrode portion corresponding to a bottom of the recess forms the upper electrode.

### Functions

Functions of the present invention will be described below.

In the active matrix substrate according to the present invention, the recess that extends through the interlayer insulating film and a part of the gate insulating film is formed in the interlayer insulating film and the gate insulating film so as to make the dielectric layer (the gate insulating film portion corresponding to the lower electrode) thinner than the gate insulating film portion corresponding to the gate electrode. Since the dielectric layer is thinner than the gate insulating film portion corresponding to the gate electrode, capacitance of the storage capacitor per unit area can be increased accordingly. This enables the storage capacitor having predetermined capacitance to be formed even if the areas of the upper electrode and the lower electrode are reduced. That is, the area of the storage capacitor can be reduced while ensuring predetermined capacitance thereof. Thus, the storage capacitor having desired capacitance can be formed without reducing the aperture ratio of a pixel.

Since the dielectric layer of the storage capacitor is formed by the gate insulating film portion corresponding to the lower electrode, and the upper electrode of the storage capacitor is formed by the pixel electrode portion corresponding to the bottom of the recess, the storage capacitor can be formed without requiring additional photomasks and additional fabrication steps.

That is, in the case of fabricating the above active matrix substrate, according to the method for fabricating the active matrix substrate of the present invention, the conductive film is first formed on the base substrate, and then is patterned to simultaneously form the gate electrode and the lower electrode in the first electrode formation step. Next, the gate insulating film is formed so as to cover the gate electrode and the lower electrode in the gate insulating film formation step, and the drain electrode is formed on the gate insulating film in the second electrode formation step. Thereafter, in the interlayer insulating film formation step, the interlayer insulating film is formed so as to cover the drain electrode and to overlap the lower electrode with the gate insulating film interposed therebetween. Then, in the insulating film patterning step, the interlayer insulating film and the gate insulating film are patterned at a time, whereby the first contact hole that reaches the drain electrode is formed in the interlayer insulating film, and the recess that extends through the interlayer insulating film and a part of the gate insulating film is formed so as to make the dielectric layer (the gate insulating film portion corresponding to the lower electrode) thinner than the gate insulating film portion corresponding to the gate electrode. Moreover, in the pixel electrode formation step, the pixel electrode is formed on the interlayer insulating film so as to electrically connect to the drain electrode via the first contact hole and to cover the recess, and the upper electrode is formed by the pixel electrode portion corresponding to the bottom of the recess. By the above steps, the storage capacitor having the dielectric layer relatively thinner than the gate insulating film portion corresponding to the gate electrode is formed without requiring additional photomasks and additional fabrication steps.

Thus, the storage capacitor having desired capacitance can be formed without causing an increase in the number of fabrication steps and a decrease in the aperture ratio.

In the active matrix substrate according to the present invention, the terminal portion, which is covered by the gate insulating film and is electrically connected to the lower electrode, may be provided on the base substrate, the second contact hole may be formed in the interlayer insulating film and the gate insulating film so as to reach the terminal portion, and the connection electrode, which is electrically connected to the terminal portion via the second contact hole and is configured to apply the common voltage to the terminal portion, may be provided on the interlayer insulating film separately from the pixel electrode. However, in the case of fabricating such an active matrix substrate, the following problem occurs if the second contact hole is formed together with the recess that extends through a part of the gate insulating film, by patterning the interlayer insulating film and the gate insulating film at a time by photolithography. Since the second contact hole is deeper than a desired recess depth, etching proceeds excessively in a region where the recess is to be formed, whereby a through hole reaching the lower electrode is formed. Accordingly, the dielectric film having a relatively small thickness cannot be satisfactorily formed, and the storage capacitor is damaged.

On the other hand, in the case where the etching suppressing layer, which is configured to suppress the etching performed to form the second contact hole, is formed on the gate insulating film corresponding to the lower electrode, and the recess extends through the etching suppressing layer, the storage capacitor having the dielectric layer with a relatively small thickness can be satisfactorily formed. That is, in fabrication of the active matrix substrate, after the etching suppressing layer is formed on the gate insulating film so as to overlap the lower electrode, and the interlayer insulating film is formed so as to cover the etching suppressing layer, the interlayer insulating film and the gate insulating film are patterned at a time by photolithography to form the recess together with the second contact hole reaching the terminal portion of the lower electrode. In this case, when patterning the interlayer insulating film and the gate insulating film, the etching suppressing layer hinders the progress of etching in the region where the recess is to be formed, whereby the etching proceeds at a lower rate in the region where the recess is to be formed than in a region where the second contact hole is to be formed. Thus, the recess can be satisfactorily formed together with the second contact hole. This reduces or eliminates the possibility of damage to the storage capacitor due to excessive etching in the region where the recess is to be formed.

Moreover, in the case where the etching suppressing layer is made of the same film as the semiconductor layer that forms the TFT, the etching suppressing layer can be formed simultaneously with the semiconductor layer. This reduces the number of fabrication steps required to form the etching suppressing layer.

The above active matrix substrate is also effective in display devices such as an LCD device, and a display device including the above active matrix substrate can be improved in display quality while simplifying the fabrication process and reducing the fabrication cost.

### Advantages of the Invention

According to the present invention, the recess, which extends through the interlayer insulating film and a part of the gate insulating film portion corresponding to the lower electrode, is formed together with the contact hole in the interlayer insulating film and the gate insulating film, the pixel electrode is formed so as to cover the recess, and the upper electrode is formed by the pixel electrode portion corresponding to the bottom of the recess. Thus, since the storage capacitor having the dielectric layer thinner than the gate insulating film portion corresponding to the gate electrode is provided, the storage capacitor having desired capacitance can be formed without causing an increase in the number of fabrication steps and a decrease in the aperture ratio. As a result, display quality can be improved while simplifying the fabrication process and reducing the fabrication cost.

### BRIEF DESCRIPTION OF THE DRAWINGS

FIG. 1 is a plan view schematically showing an LCD device according to an embodiment of the present invention.

FIG. 2 is a cross-sectional view schematically showing the LCD device taken along line II-II in FIG. 1.

FIG. 3 is a plan view schematically showing a configuration of a pixel and terminal portions in an active matrix substrate of the embodiment.

FIG. 4 is a cross-sectional view schematically showing the active matrix substrate taken along lines A-A, B-B, and C-C in FIG. 3.

FIG. 5 is a cross-sectional view showing a state in which a metal stacked film has been formed in a first electrode formation step in a method for fabricating an active matrix substrate according to an embodiment of the present invention.

FIG. 6 is a cross-sectional view showing a state in which a gate electrode and a lower electrode have been formed in the first electrode formation step in the method for fabricating an active matrix substrate according to the embodiment of the present invention.

FIG. 7 is a cross-sectional view showing a gate insulating film formation step in the method for fabricating an active matrix substrate according to the embodiment of the present invention.

FIG. 8 is a cross-sectional view showing a state in which a semiconductor layer formation portion and an etching suppressing layer are formed in a second electrode formation step in the method for fabricating an active matrix substrate according to the embodiment of the present invention.

FIG. 9 is a cross-sectional view showing a state in which a semiconductor layer, a source electrode, and a drain electrode are formed in the second electrode formation step in the method for fabricating an active matrix substrate according to the embodiment of the present invention.

FIG. 10 is a cross-sectional view showing an interlayer insulating film formation step in the method for fabricating an active matrix substrate according to the embodiment of the present invention.

FIG. 11 is a cross-sectional view showing an insulating film patterning step in the method for fabricating an active matrix substrate according to the embodiment of the present invention.

### DESCRIPTION OF EMBODIMENTS

An embodiment of the present invention will be described in detail below with reference to the accompanying drawings. Note that the present invention is not limited to the following embodiment.

### Embodiment of the Invention

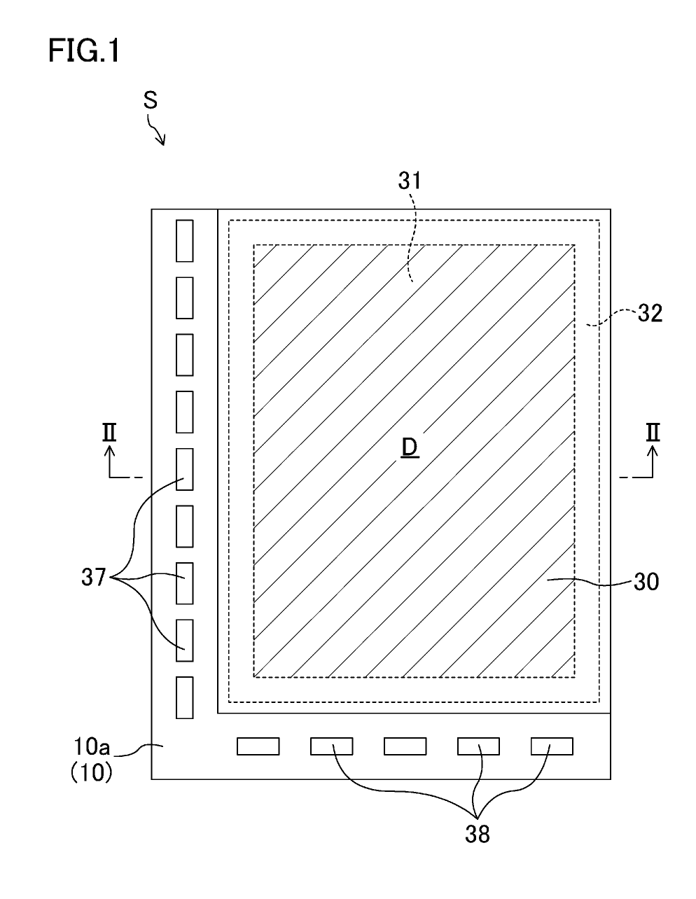

FIGS. 1 to 11 show an embodiment of an active matrix substrate, an LCD device including the same, and a method for fabricating an active matrix substrate according of the present invention.

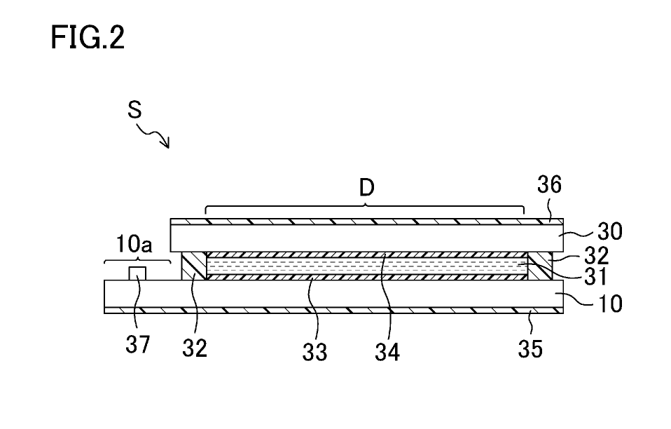

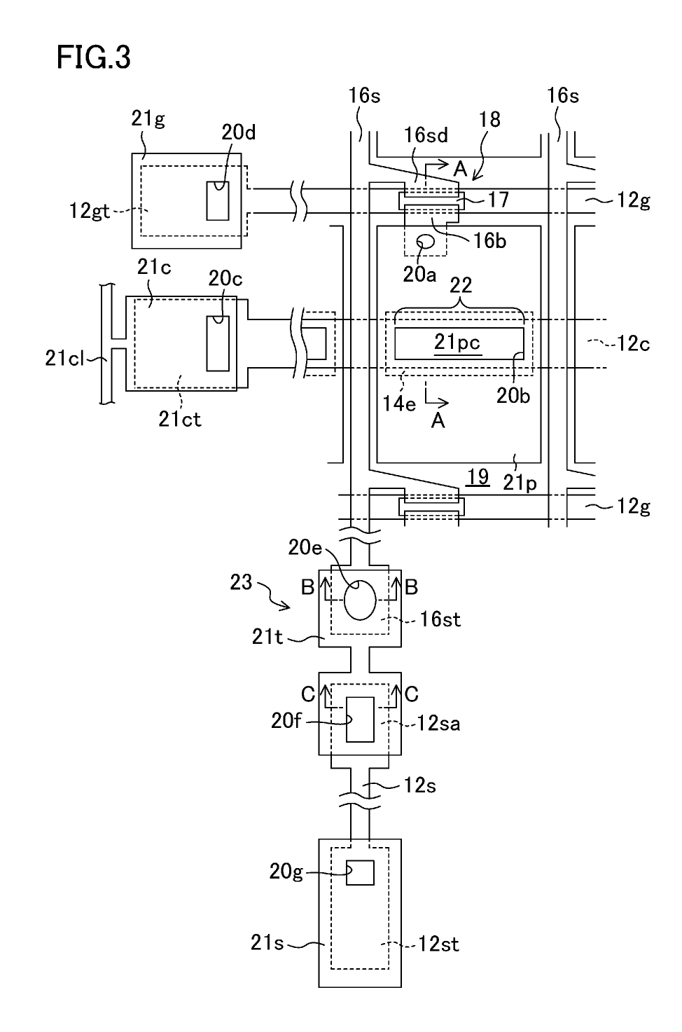

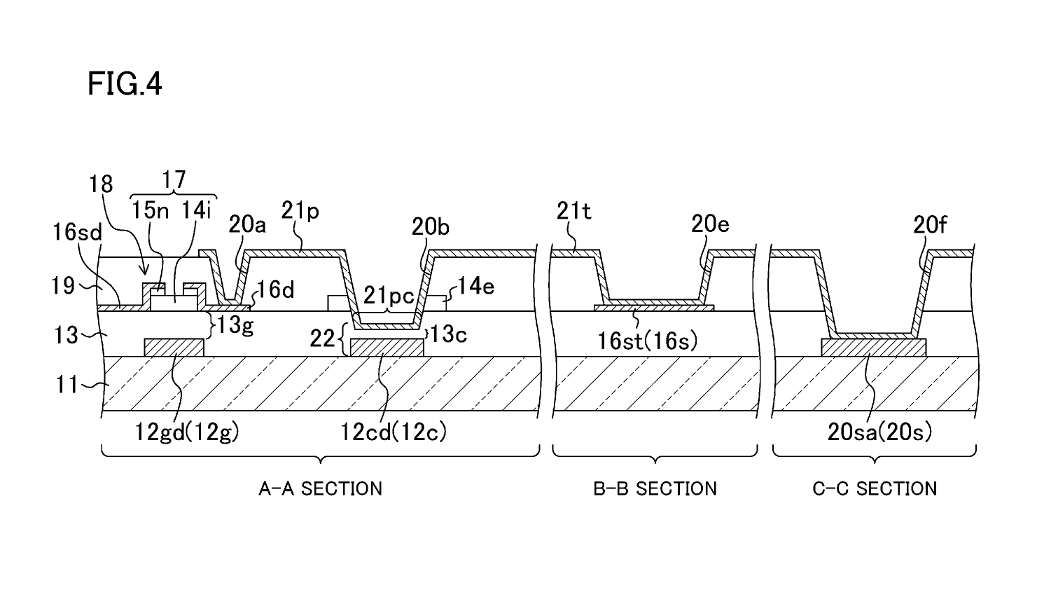

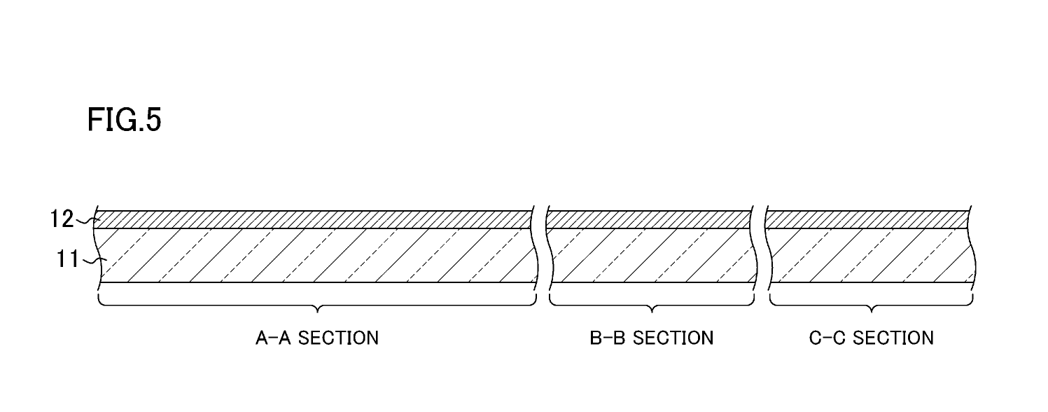

FIG. 1 is a plan view schematically showing an LCD device S of the present embodiment. FIG. 2 is a cross-sectional view schematically showing the LCD device S taken along line II-II in FIG. 1. FIG. 3 is a plan view schematically showing a configuration of a pixel and terminal portions in an active matrix substrate 10 of the LCD device S. FIG. 4 is a cross-sectional view schematically showing a cross section of a main part of the pixel and the terminal portions in FIG. 3. FIGS. 5 to 11 are diagrams illustrating a method for fabricating the active matrix substrate 10 according to the present embodiment, as described later. Note that in FIG. 1, a polarizer 36 is not shown for convenience of description. FIG. 4 shows cross-sections taken along lines A-A, B-B, and C-C in FIG. 3 in this order from left to right in the figure.

<Configuration of LCD Device S>

As shown in FIGS. 1 and 2, the LCD device S includes: the active matrix substrate 10; a counter substrate 30 placed so as to face the active matrix substrate 10; a liquid crystal layer 31 provided between the active matrix substrate 10 and the counter substrate 30; and a sealant 32 configured to bond the active matrix substrate 10 to the counter substrate 30 and to enclose the liquid crystal layer 31.

Each of the active matrix substrate 10 and the counter substrate 30 is formed in, e.g., a rectangular shape. As shown in FIG. 2, alignment films 33, 34 are respectively provided on the surfaces of the active matrix substrate 10 and the counter substrate 30 which are located on the side of the liquid crystal layer 31, and polarizers 35, 36 are respectively provided on the opposite surfaces of the active matrix substrate 10 and the counter substrate 30 from the liquid crystal layer 31. The liquid crystal layer 31 is made of a nematic liquid crystal material having electrooptical characteristics, etc. As shown in FIG. 1, the sealant 32 is formed in the shape of, e.g., a rectangular frame so as to extend along each side of the counter substrate 30.

In the LCD device S, a display region D configured to display an image is defined inside the sealant 32 in a region where the active matrix substrate 10 overlaps the counter substrate 30. Outside the display region D protrudes the active matrix substrate 10 in an “L” shape etc. beyond the counter substrate 30, forming a mount portion 10a.

The display region D is, e.g., a rectangular region, in which a plurality of pixels, each of which is a minimum unit of an image, are arranged in a matrix pattern. On the other hand, a plurality of gate driver integrated circuits (hereinafter referred to as “IC”) chips 37 are mounted on one side (the left side in FIG. 1) of the mount portion 10a with anisotropic conductive films (hereinafter referred to as the “ACFs”) interposed therebetween, and a plurality of source driver IC chips 38 are mounted on another side (the lower side in FIG. 1) of the mount portion 10a with ACFs interposed therebetween.

<Configuration of Active Matrix Substrate 10>

As shown in FIGS. 3 and 4, the active matrix substrate 10 has an insulating substrate 11 as a base substrate, and in the display region D, includes: a plurality of gate lines 12g provided on the insulating substrate 11 so as to extend parallel to each other; a plurality of storage capacitor lines 12c each provided between adjoining ones of the gate lines 12g so as to extend parallel to each other; a gate insulating film 13 provided so as to overlap the gate lines 12g and the storage capacitor lines 12c; and a plurality of source lines 16s provided on the gate insulating film 13 so as to extend parallel to each other in a direction crossing the gate lines 12g. The gate lines 12g and the source lines 16s are generally arranged in a grid pattern so as to define each pixel. The storage capacitor lines 12c extend across the central portions of those pixels arranged in the direction in which the gate lines 14a extend.

The active matrix substrate 10 further includes: TFTs 18 and storage capacitors 22 provided at each pixel; an interlayer insulating film 19 provided over substantially the entire surface of the active matrix substrate 10 so as to cover the TFTs 18; and a plurality of pixel electrodes 21p arranged in a matrix pattern on the interlayer insulating film 19 so as to correspond to the pixels.

<Configuration of TFT 18 and Storage Capacitor 22>

As shown in FIG. 4 (an A-A section), each of the TFTs 18 is a bottom-gate TFT and includes: a gate electrode 12gd provided on the insulating substrate 11; the gate insulating film 13 provided so as to cover the gate electrode 12gd; a semiconductor layer 17 provided in an island shape at a position overlapping the gate electrode 12gd with the gate insulating film 13 interposed therebetween; and a source electrode 16sd and a drain electrode 16d which are connected to the semiconductor layer 17 and are separated from each other.

The gate electrode 12gd is formed by a part of the gate line 12g. The semiconductor layer 17 is formed by sequentially stacking an intrinsic amorphous silicon layer 14i and an n+ amorphous silicon layer 15n. The n+ amorphous silicon layer 15n is divided into two portions in the width direction (the lateral direction in FIG. 4) of the gate electrode 12gd by partially removing a central portion of the n+ amorphous silicon layer 15n so as to expose the intrinsic amorphous silicon layer 14i. The exposed portion of the intrinsic amorphous silicon layer 14i forms a channel portion.

As shown in FIG. 3, the source electrode 16sd is a portion laterally protruding from the source line 16s, and as shown in FIG. 4, is provided so as to overlap one of the two divided portions of the n+ amorphous silicon layer 15n. The drain electrode 16d is provided so as to overlap the other portion of the n+ amorphous silicon layer 15n. A contact hole (a first contact hole) 20a extending to the drain region 16d is formed in the interlayer insulating film 19, and the pixel electrode 21p is connected to the drain electrode 16d via the contact hole 20a.

Moreover, a recess 20b is formed at each pixel in the interlayer insulating film 19 and the gate insulating film 13. The recess 20b extends through the interlayer insulating film 19 and a part of the gate insulating film 13 so as to make a gate insulating film portion 13c corresponding to the storage capacitor line 12c partially thinner than a gate insulating film portion 13g corresponding to the gate electrode 12gd in the pixel. This recess 20b is formed so that its bottom corresponds to the entire width of the storage capacitor line 12c, and is covered by the pixel electrode 21p.

An etching suppressing layer 14e configured to suppress etching when forming the recess 20b remains in a frame shape on the gate insulating film 13 so as to surround the recess 20b. That is, the recess 20b extends through the etching suppressing layer 14e on the gate insulating film 13 corresponding to the storage capacitor line 12c. This etching suppressing layer 14 is made of the same film as the intrinsic amorphous silicon layer 14i of the semiconductor layer 17.

As shown in FIG. 4 (the A-A section), each storage capacitor 22 includes: a lower electrode 12cd provided on the insulating substrate 11 and covered by the gate insulating film 13; a dielectric layer 13c formed by a gate insulating film portion corresponding to the lower electrode 12cd; and an upper electrode 21pc provided so as to overlap the lower electrode 12cd with the dielectric layer 13b interposed therebetween.

The lower electrode 12cd is formed by a part of the storage capacitor line 12c corresponding to the recess 20b, and is made of the same film as the gate electrode 12gd (the gate line 12g). The upper electrode 21pc is formed by a pixel electrode portion corresponding to the bottom of the recess 20b. The dielectric layer 13c is formed by a relatively thin gate insulating film portion between the lower electrode 12cd and the upper electrode 21pc.

Each storage capacitor line 12c extends so that both ends thereof reach a region where the sealant 32 is provided, and each end of the storage capacitor line 12c forms a storage capacitor terminal portion 12ct shown in FIG. 3. A contact hole (a second contact hole) 20c is continuously formed in the interlayer insulating film 19 and the gate insulating film 13 so as to reach the storage capacitor terminal portion 12ct. A common connection electrode 21c connected to the storage capacitor terminal portion 12ct via the contact hole 20c is provided on the interlayer insulating film 19. This common connection electrode 21c is connected to a common line 21cl, and is electrically connected to a common electrode of the counter substrate 30, described below, by so-called common transfer. The common connection electrode 21c forms an electrode configured to apply a common voltage, which is similar to that of the common electrode, to the storage capacitor terminal portion 12ct.

Each gate line 14a is extended to the mount portion 10a to reach a region where the gate driver IC chips 37 are mounted, and the extended end portion of the gate line 14a forms a gate terminal portion 12gt shown in FIG. 3. The gate terminal portion 12gt is connected to a gate connection electrode 21g on the interlayer insulating film 19 via a contact hole 20d continuously formed in the interlayer insulating film 19 and the gate insulating film 13. The gate connection electrode 21g forms an electrode configured to electrically connecting to the gate driver IC chip 37.

As shown in FIG. 3, each source line 16s is extended to the mount portion 10a to reach a region where the source driver IC chips 38 are mounted, via an interconnection portion 28 configured to interconnect to a lead line 12s made of the same film as the gate lines 12g, and the extended end of the interconnection portion 23 forms a source terminal portion 12st.

The interconnection portion 23 is provided in, e.g., a region where the sealant 32 is placed. As shown in FIG. 4 (the B-B section), in the interconnection portion 23, a lead end 16st, which is provided in the same layer as the source line 16s in the display region D, is connected to an interconnection electrode 21t provided on the interlayer insulating film 19, via a contact hole 20e formed in the interlayer insulating film 19. The interconnection electrode 21t is connected to one end 12sa of the lead line 12s via a contact hole 20f continuously formed in the interlayer insulating film 19 and the gate insulating film 13 as shown in FIG. 4 (the C-C section).

The source terminal portion 12st, which is formed by the other end of the lead line 12s, is connected to a source connection electrode 21s provided on the interlayer insulating film 19, via a contact hole 20g continuously formed in the interlayer insulating film 19 and the gate insulating film 13. The source connection electrode 21s forms an electrode configured to electrically connect to the source driver IC chip 38.

<Configuration of Counter Substrate 30>

Although not shown in the figures, the counter substrate 30 includes: a black matrix provided in a grid pattern on an insulating substrate so as to correspond to the gate lines 12g and the source lines 16s; color filters of a plurality of colors including red, green, and blue layers periodically arranged between the grid lines of the black matrix; a common electrode provided so as to cover the black matrix and the color filters; and a columnar photo spacer provided on the common electrode.

<Operation of LCD Device S>

In the LCD device S having the above configuration, when the TFT 18 in each pixel is turned on in response to a gate signal sent from the gate driver IC chip 37 to the gate electrode 12gd through the gate line 12g, a source signal is sent from the source driver IC chip 38 to the source electrode 16sd through the source line 16s to write a predetermined amount of charge to the pixel electrode 21p through the semiconductor layer 17 and the drain electrode 16d. At this time, a potential difference is generated between the pixel electrode 21p of the active matrix substrate 10 and the common electrode of the counter substrate 30, whereby a predetermined voltage is applied to the liquid crystal layer 31. When the TFT 18 is off, storage capacitance formed between the lower electrode 12cd and the upper electrode 21pc in the storage capacitor 22 suppresses a decrease in an electric potential written to the pixel electrode 21p. In the LCD device S, the alignment state of liquid crystal molecules is changed in each pixel according to the level of the voltage applied to the liquid crystal layer 31, thereby adjusting light transmittance of the liquid crystal layer 31 to display a desired image.

Fabrication Method

A method for fabricating the active matrix substrate 10 and the LCD device S will be described below with reference to FIGS. 5 to 11.

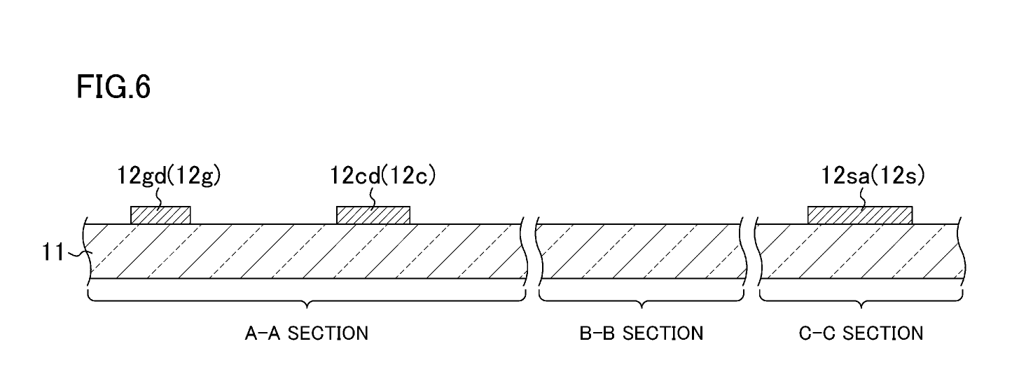

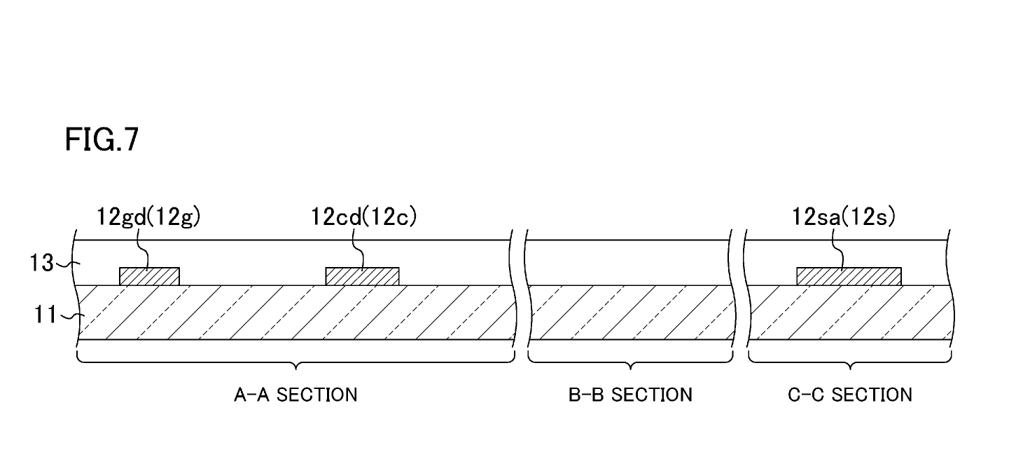

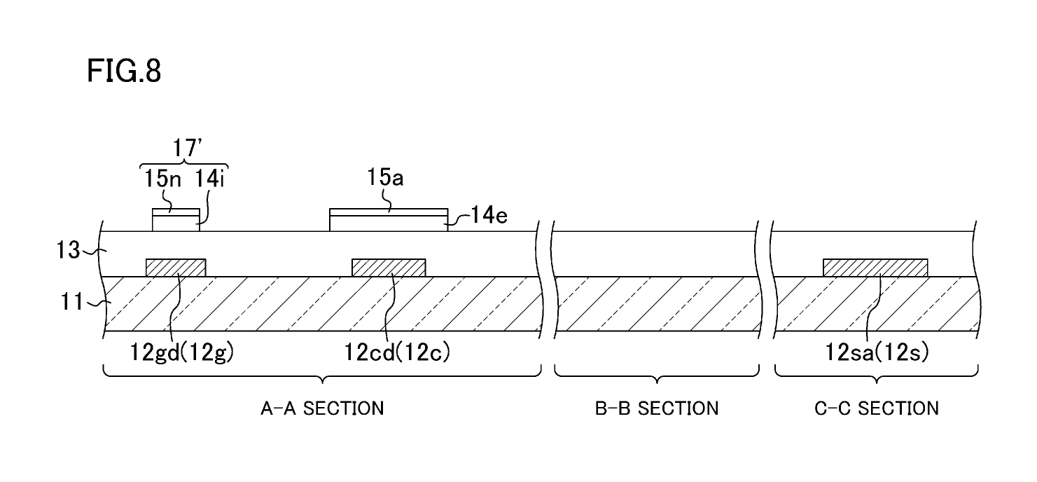

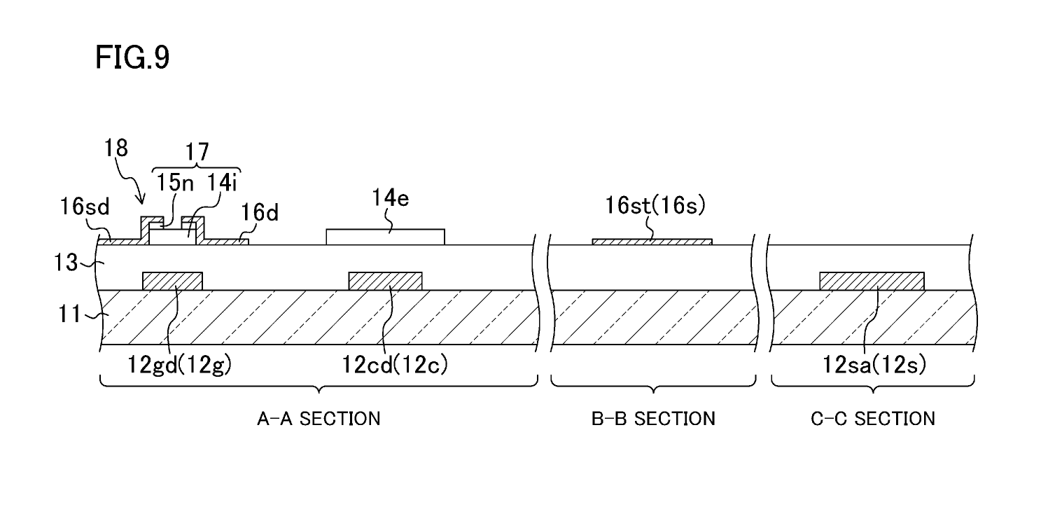

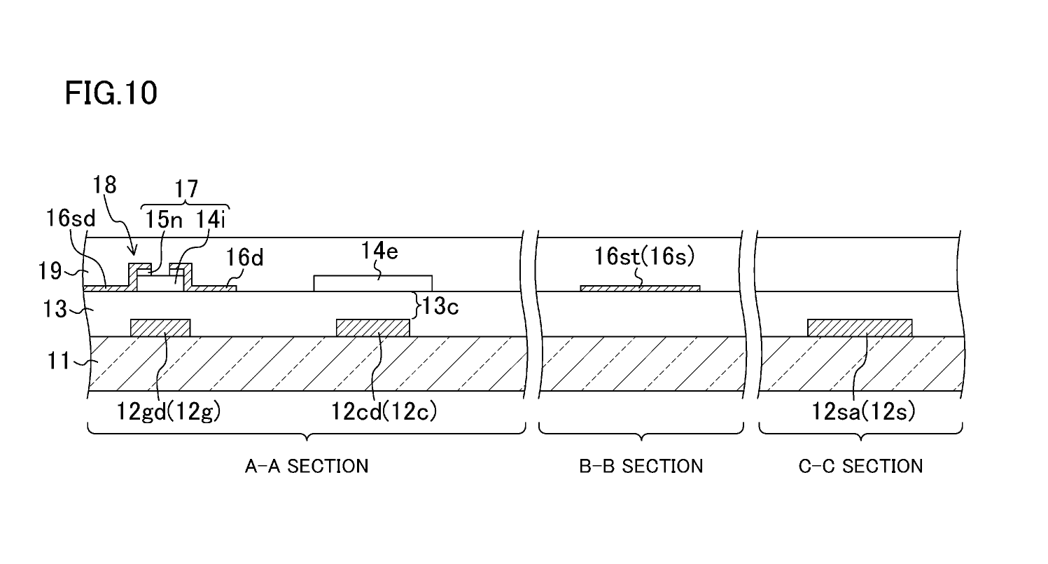

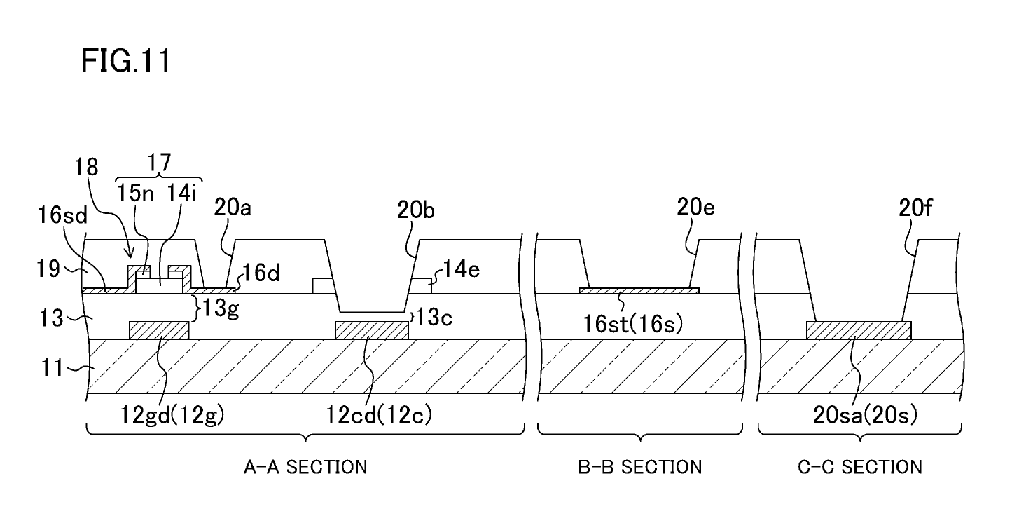

FIGS. 5 and 6 are cross-sectional views illustrating a method for forming the gate electrode 12gd and the lower electrode 12cd. FIG. 7 is a cross-sectional view showing a state in which the gate insulating film 13 has been formed. FIGS. 8 and 9 are cross-sectional views illustrating a method for forming the semiconductor layer 17, the etching suppressing layer 14e, the source electrode 16sd, and the drain electrode 16d. FIG. 10 is a cross-sectional view showing a state in which the interlayer insulating film 19 has been formed. FIG. 11 is a cross-sectional view showing a state in which the interlayer insulating film 19 and the gate insulating film 13 have been patterned. Note that FIGS. 5 to 11 show a portion corresponding to the cross sections (the A-A section, the B-B section, and the C-C section) in FIG. 4.

The method for fabricating the LCD device S according to the present embodiment includes an active matrix substrate fabrication step, a counter substrate fabrication step, a bonding step, and a mounting step.

<Active Matrix Substrate Fabrication Step>

The active matrix substrate fabrication step includes a first electrode formation step, a gate insulating film formation step, a second electrode formation step, an interlayer insulating film formation step, an insulating film patterning step, and a pixel electrode formation step.

<First Electrode Formation Step>

As shown in FIG. 5, e.g., a titanium film, an aluminum film, a titanium film, etc. are sequentially formed by a sputtering method on an insulating substrate 11 such as a glass substrate, which has been prepared in advance, to form a metal stacked film 12. Then, a resist layer is formed by using a first photomask, and the metal stacked film 12 is patterned by photolithography in which etching is performed by using the resist layer as a mask, thereby forming a gate line 12g, a gate electrode 12gd, a storage capacitor line 12c, a lower electrode 12cd, and a lead line 12s as shown in FIG. 6. Thereafter, the resist layer used as a mask is removed by ashing.

<Gate Insulating Film Formation Step>

As shown in FIG. 7, e.g., a silicon nitride film etc. is formed by a plasma chemical vapor deposition (CVD) method on the substrate on which the gate electrode 12gd, the lower electrode 12cd, etc. have been formed in the first electrode formation step, whereby a gate insulating film 13 is formed so as to cover the gate electrode 12gd and the lower electrode 12cd.

<Second Electrode Formation Step>

For example, an intrinsic amorphous silicon film, and an n+ amorphous silicon film doped with phosphorus (P) are successively formed by a plasma CVD method on the substrate having the gate insulating film 13 formed in the gate insulating film formation step, thereby forming a semiconductor stacked film. Then, a resist layer is formed by using a second photomask, and the semiconductor stacked film is patterned by photolithography in which etching is performed by using the resist layer as a mask, whereby a semiconductor layer formation portion 17′ as a stack of the intrinsic amorphous silicon layer 14i and the n+amorphous silicon layer 15n, and an etching suppressing layer 14e having the n+amorphous silicon layer 15a stacked thereon are formed as shown in FIG. 8. Thereafter, the resist layer used as a mask is removed by etching.

Next, for example, an aluminum film, a titanium film, etc. are sequentially stacked by a sputtering method on the substrate on which the semiconductor layer formation portion 17′ and the etching suppressing layer 14e have been formed, thereby forming a metal stacked film. Then, a resist layer is formed by using a third photomask, and the metal stacked film is patterned by photolithography in which etching is performed by using the resist layer as a mask, thereby forming a source line 16s, a source electrode 16sd, and a drain electrode 16d on the gate insulating film 13. Thereafter, the resist layer used as a mask is removed by ashing.

Subsequently, the n+ amorphous silicon layer 15n in the semiconductor layer formation portion 17′ is etched by using the source electrode 16sd and the drain electrode 16d as a mask, thereby patterning a channel portion to form a semiconductor layer 17 and a TFT 18 including the semiconductor layer 17, as shown in FIG. 9. At this time, the n+ amorphous silicon layer 15a on the etching suppressing layer 14e is also removed by etching.

<Interlayer Insulating Film Formation Step>

As shown in FIG. 10, e.g., a silicon nitride film is formed by a plasma CVD method over the substrate having the TFT 18 formed thereon in the drain electrode formation step, whereby an interlayer insulating film 19 is formed so as to cover the drain electrode 16d and to overlap the lower electrode 12cd with the gate insulating film 13 and the etching suppressing layer 14e interposed therebetween. Up to this point in the process, the thickness of a gate insulating film portion 13c corresponding to the lower electrode 12cd is substantially equal to that of a gate insulating film portion 13g corresponding to the gate electrode 12gd.

<Insulating Film Patterning Step>

A resist layer is formed by using a fourth photomask, and the interlayer insulating film 19 formed in the interlayer insulating film formation step and the gate insulating film 13 are patterned at a time by photolithography in which dry etching is performed with a fluorinated gas such as, e.g., a CF₄ gas by using the resist layer as a mask. As a result, as shown in FIG. 11, contact holes 20a, 20c, 20d, 20e, 20f, and 20g are formed, and a recess 20b extending through the interlayer insulating film 19 and a part of the gate insulating film 13 is formed so as to make the gate insulating film portion 13c corresponding to the lower electrode 12cd thinner than the gate insulating film portion 13g corresponding to the gate electrode 12gd. Thus, a dielectric layer 13c of a storage capacitor 22 is formed with a relatively small thickness.

At this time, since the drain electrode 16d and the lead end 16st of the source line 16s function as an etching stopper, the etching in the regions where the contact holes 20a, 20e are to be formed stops when the drain electrode 16d and the lead end 16st of the source line 16s are exposed. On the other hand, the etching in the region where the recess 20b is to be formed is suppressed by the etching suppressing layer 14e, and the etching thus proceeds at a lower rate in this region than in the regions where the contact holes 20c, 20d, 20f, and 20g are formed. This enables the recess 20b to be satisfactorily formed together with the contact holes 20a, 20c, 20d, 20e, 20f, and 20g. This reduces or eliminates the possibility of damage to the storage capacitor 22 due to excessive etching in the region where the recess 20b is to be formed.

Thereafter, the resist layer used as a mask is removed by ashing.

<Pixel Electrode Formation Step>

For example, an indium tin oxide (ITO) film is formed by a sputtering method over the substrate in which the contact holes 20a, 20c, 20d, 20e, 20f, and 20g and the recess 20b have been formed in the insulating film patterning step. Then, a resist layer is formed by using a fifth photomask, and the ITO film is patterned by photolithography in which etching is performed by using the resist layer as a mask, whereby a pixel electrode 21p is formed so as to connect to the drain electrode 16d via the contact hole 20a and to cover the recess 20b, and a pixel electrode portion corresponding to the bottom of the recess 20b forms an upper electrode 21pc. Thus, the upper electrode 21pc is formed simultaneously with the pixel electrode 21p. At this time, a common connection electrode 21c, a gate connection electrode 21g, and an interconnection electrode 21t, and a source connection electrode 21s are also formed simultaneously from the ITO film. Thereafter, the resist layer used as a mask is removed by ashing.

The active matrix substrate 10 shown in FIG. 4 can be fabricated in this manner.

<Counter Substrate Formation Step>

First, a negative acrylic photosensitive resin having fine particles of, e.g., carbon etc. dispersed therein is applied by a spin coating method to the entire surface of an insulating substrate such as a glass substrate. The applied photosensitive resin is exposed to light via a photomask, and then is developed, thereby patterning the photosensitive resin to form a black matrix.

Next, a red, green, or blue-colored negative acrylic photosensitive resin colored, e.g., red, green, or blue is applied to the substrate having the black matrix formed thereon. The applied photosensitive resin is exposed to light via a photomask, and then is developed, thereby patterning the photosensitive resin to form a colored layer of a selected color (e.g., a red layer). A similar process is repeated to form colored layers of the other two colors (e.g., a green layer and a blue layer), thereby forming color filters.

Then, an ITO film, for example, is formed by a sputtering method over the substrate having the color filters formed thereon, thereby forming a common electrode. Subsequently, a positive phenol novolac photosensitive resin is applied by a spin coating method to the substrate having the common electrode formed thereon. The applied photosensitive resin is exposed to light via a photomask, and then is developed, thereby forming a photo spacer.

The counter substrate 30 can be fabricated in this manner.

<Bonding Step>

First, a polyimide resin is applied to the surface of the active matrix substrate 10 by a printing method, and then a rubbing process is performed to form an alignment film 33. A polyimide resin is applied also to the surface of the counter substrate 30 by a printing method, and then a rubbing process is performed to form an alignment film 34.

Next, a sealant 32 made of an ultraviolet (UV)-curable, thermosetting resin etc. is applied in the shape of a rectangular frame to the counter substrate 30 having the alignment film 34 provided thereon, by using, e.g., a dispenser etc. Subsequently, a predetermined amount of liquid crystal material is dropped onto a region inside the sealant 32 on the counter substrate 30 on which the sealant 32 has been applied.

Then, the counter substrate 30 having the liquid crystal material dropped thereon and the active matrix substrate 10 having the alignment film 33 provided thereon are bonded together under a reduced pressure, and the bonded body of the counter substrate 30 and the active matrix substrate 10 is exposed to atmospheric pressure to press the surfaces of the bonded body. Moreover, the sealant 32 of the bonded body is irradiated with UV light to preliminarily cure the sealant 32, and then the resultant bonded body is heated to permanently cure the sealant 32, thereby bonding the active matrix substrate 10 to the counter substrate 30.

Thereafter, polarizers 35, 36 are respectively bonded to the surfaces of the active matrix substrate 10 and the counter substrate 30 that have been bonded together.

<Mounting Step>

Anisotropic conductive films (ACFs) are respectively formed on the regions where driver IC chips 37, 38 are to be mounted in the mount portion 10a of the bonded body having the polarizers 35, 36 bonded to both surfaces thereof. Then, the driver IC chips 37, 38 are thermocompression bonded to the mount portion 10a with the ACFs interposed therebetween, thereby mounting the driver IC chips 37, 38 on the bonded body.

The LCD device S shown in FIG. 1 can be fabricated by the above steps.

### Advantages of First Embodiment

As described above, in the active matrix substrate 10, the LCD device S including the same, and the method for fabricating the active matrix substrate 10 and the LCD device S according to the present embodiment, the recess 20b that extends through a part of the gate insulating film 13 is formed in the interlayer insulating film 19 and the gate insulating film 13 so as to make the dielectric layer (the gate insulating film portion corresponding to the lower electrode 12cd) 13c of the storage capacitor 22 thinner than the gate insulating film portion 13g corresponding to the gate electrode 12gd. Since the dielectric layer 13c is thinner than the gate insulating film portion 13g corresponding to the gate electrode 12gd, capacitance of the storage capacitor 22 per unit area can be increased accordingly. This enables the storage capacitor 22 having predetermined capacitance to be formed even if the areas of the upper electrode 21pc and the lower electrode 12cd are reduced. That is, the area of the storage capacitor 22 can be reduced while ensuring predetermined capacitance thereof. Thus, the storage capacitor 22 having desired capacitance can be formed without reducing the aperture ratio of the pixel.

Moreover, since the dielectric layer 13c of the storage capacitor 22 is formed by the gate insulating film portion corresponding to the lower electrode 12cd, and the upper electrode 21pc of the storage capacitor 22 is formed by the pixel electrode portion corresponding to the bottom of the recess 20b, the dielectric layer 13c having a relatively small thickness can be formed by using the gate insulating film formation step and the insulating film patterning step, and the upper electrode 21pc can be formed by using the pixel electrode formation step, as illustrated in the active matrix substrate fabrication step. In this case, the active matrix substrate 10 can be fabricated by using five photomasks (the first to fifth photomasks), while, e.g., at least six photomasks are required to form the dielectric layer of the storage capacitor separately from the gate insulating film 13. Thus, the storage capacitor 22 having the dielectric layer 13c thinner than the gate insulating film portion 13g corresponding to the gate electrode 12gd can be formed without requiring additional photomasks and additional fabrication steps.

Accordingly, the storage capacitor 22 having desired capacitance can be formed without causing an increase in the number of fabrication steps and a decrease in the aperture ratio, whereby display quality can be improved while simplifying the fabrication process and reducing the fabrication cost.

Note that although the above embodiment is described with respect to an example in which one rectangular recess 20b is formed at each pixel, the present invention is not limited to this, and a plurality of small recesses may be formed at each pixel. The recess 20b may have other shapes such as a circular shape, an elliptical shape, etc., and may have a larger dimension in the width direction than the storage capacitor line 12c as viewed in plan.

Although the resist layers used as masks to pattern the interlayer insulating film 19, the gate insulating film 13, etc. are removed in the above embodiment, the pixel electrode 21p, the gate connection electrode 21g, etc. may be formed with the resist layers being left.

Although the active matrix substrate 10 forming the LCD device S is described in the above embodiment, the present invention is not limited to this, and is applicable to other display devices such as an organic electro luminescence (EL) display device, active matrix substrates forming such display devices, and methods for fabricating such display devices and active matrix substrates.

### INDUSTRIAL APPLICABILITY

As described above, the present invention is useful for an active matrix substrate, an LCD device including the active matrix substrate, and a method for fabricating the active matrix substrate and the LCD device. In particular, the present invention is suitable for an active matrix substrate for which a storage capacitor having desired capacitance is desired to be formed without causing an increase in the number of fabrication steps and a decrease in the aperture ratio of the pixel, an LCD device including the active matrix substrate, and a method for fabricating the active matrix substrate and the LCD device.

### DESCRIPTION OF REFERENCE CHARACTERS

S LCD Device
10 Active Matrix Substrate
11 Insulating Substrate (Base Substrate)
12 Metal Stacked Film (Conductive Film)
12gd Gate Electrode
12cd Lower Electrode
12ct Common Terminal Portion
13 Gate Insulating Film
13c Dielectric Layer
13g Gate Insulating Film Portion Corresponding to Gate Electrode
14e Etching Suppressing Layer
16d Drain Electrode
17 Semiconductor Layer
18 TFT (Thin Film Transistor)
19 Interlayer Insulating Film
20a Contact Hole (First Contact Hole)
20b Recess
20c Contact Hole (Second Contact Hole)
21p Pixel Electrode
21pc Upper Electrode
22 Storage Capacitor
30 Counter Substrate
31 Liquid Crystal Layer

1. An active matrix substrate, comprising:
a base substrate;
a thin film transistor having a gate electrode provided on the base substrate, a gate insulating film provided so as to cover the gate electrode, and a drain electrode provided on the gate insulating film;
a storage capacitor having a lower electrode provided on the base substrate and covered by the gate insulating film, a dielectric layer formed by a gate insulating film portion corresponding to the lower electrode, and an upper electrode provided so as to overlap the lower electrode with the dielectric layer interposed therebetween;
an interlayer insulating film provided so as to cover the thin film transistor, and having a first contact hole that reaches the drain electrode; and
a pixel electrode provided on the interlayer insulating film, and electrically connected to the drain electrode via the first contact hole, wherein
a recess, which extends through the interlayer insulating film and a part of the gate insulating film and is covered by the pixel electrode, is formed in the interlayer insulating film and the gate insulating film so as to make the dielectric layer thinner than a gate insulating film portion corresponding to the gate electrode, and
the upper electrode is formed by a pixel electrode portion corresponding to a bottom of the recess.

2. The active matrix substrate of claim 1, wherein
a terminal portion, which is covered by the gate insulating film and is electrically connected to the lower electrode, is provided on the base substrate,
a second contact hole is formed in the interlayer insulating film and the gate insulating film so as to reach the terminal portion,
a connection electrode, which is electrically connected to the terminal portion via the second contact hole and is configured to apply a common voltage to the terminal portion, is provided separately from the pixel electrode on the interlayer insulating film,
the thin film transistor further has a semiconductor layer, which overlaps the gate electrode with the gate insulating film interposed therebetween and is electrically connected to the drain electrode, and
the recess extends through an etching suppressing layer on the gate insulating film corresponding to the lower electrode, the etching suppressing layer being made of a same film as the semiconductor layer.

3. A liquid crystal display device, comprising:
the active matrix substrate of claim 1;
a counter substrate placed so as to face the active matrix substrate; and
a liquid crystal layer provided between the active matrix substrate and the counter substrate.

4. A method for fabricating an active matrix substrate, the active matrix substrate including
a thin film transistor having a gate electrode provided on a base substrate, a gate insulating film provided so as to cover the gate electrode, and a drain electrode provided on the gate insulating film, and
a storage capacitor having a lower electrode provided on the base substrate and covered by the gate insulating film, a dielectric layer formed by a gate insulating film portion corresponding to the lower electrode, and an upper electrode provided so as to overlap the lower electrode with the dielectric layer interposed therebetween, the method comprising:
a first electrode formation step of forming a conductive film on the base substrate, and then patterning the conductive film to simultaneously form the gate electrode and the lower electrode;
a gate insulating film formation step of forming the gate insulating film so as to cover the gate electrode and the lower electrode;
a second electrode formation step of forming the drain electrode on the gate insulating film;
an interlayer insulating film formation step of forming an interlayer insulating film so as to cover the drain electrode and to overlap the lower electrode with the gate insulating film interposed therebetween;
an insulating film patterning step of patterning the interlayer insulating film and the gate insulating film at a time to form in the interlayer insulating film a contact hole that reaches the drain electrode, and to form a recess, which extends through the interlayer insulating film and a part of the gate insulating film, so as to make the dielectric layer thinner than a gate insulating film portion corresponding to the gate electrode; and
a pixel electrode formation step of forming a pixel electrode on the interlayer insulating film having the contact hole formed therein, so that the pixel electrode electrically connects to the drain electrode via the contact hole and covers the recess, wherein
a pixel electrode portion corresponding to a bottom of the recess forms the upper electrode.
